(19) United States
(12) Patent Application Publication
(10) Pub. No.: US 2012/0181562 A1
(43) Pub. Date: Jul. 19, 2012

(54) PACKAGE HAVING A LIGHT-EMITTING ELEMENT AND METHOD OF FABRICATING THE SAME

(75) Inventors: Wen-Hao Lee, Taichung (TW); Hisen-Wen Chen, Taichung (TW); Guang-Hwa Ma, Taichung (TW)

(73) Assignee: SILICONWARE PRECISION INDUSTRIES CO., LTD., Taichung (TW)

(21) Appl. No.: 13/351,812

(22) Filed: Jan. 17, 2012

(30) Foreign Application Priority Data
Jan. 18, 2011 (TW) 100101719

(51) Int. Cl. H01L 33/44; H01L 33/62

(52) U.S. Cl. 257/98; 438/27; 257/E33.061; 257/E33.066

(57) ABSTRACT

A package includes at least a chip encapsulated by an encapsulant. Conductive bumps are disposed on a first surface of the chip, for a circuit board to be disposed thereon. A phosphor layer is formed on a second surface of the chip opposing the first surface. The package further comprises a light-pervious mask that covers the phosphor layer. Since the phosphor layer and the light-pervious mask are directly formed on the chip, the chip is prevented from being disposed in the groove of the substrate. As a result, the wet etching process is omitted, and the fabrication cost is reduced. A method of fabricating the package is also provided.

### BACKGROUND OF THE INVENTION

1. Field of the Invention

This invention relates to packages and methods of fabricating the same, and, more particularly, to a package having a light-emitting element and a method of fabricating the same.

2. Description of Related Art

With the rapid development of the electronic industry, electronic products are becoming low-profiled and compact-sized and have a variety of astonishing functionalities.

Referring to U.S. Pat. No. 6,531,328 or FIG. 1, a cross-sectional view of a package 1 having a light-emitting element of the prior art is provided. The package 1 is in a chip-on-chip (COC) manner or provides a single silicon substrate. A silicon substrate 10 is etched in a wet etching process, and a groove 100 and a plurality of through holes 101 are thus formed. The groove 100 has an inclined wall 100a, and a light-emitting chip 11 is provided at the bottom of the groove 100 and is electrically connected to ends of the through holes 101 via conductive wires 13. A reflective layer 14 is formed on the inclined wall 100a of the groove 100. In general, the reflective layer 14 is made of aluminum or silver that has a high reflectance.

During the formation of the groove 100, the crystalline lattice arrangement of silicon lattice in the silicon substrate 10 must be considered, in order for the groove 100 to have the inclined wall 100a as desired (e.g., having an inclined angle of 54.74°) and the package 1 to achieve a desired light-reflective efficiency. Therefore, it takes more time, consumes more etch liquid and increases the cost of etching equipment to form an inclined wall having a better angle.

Moreover, it is difficult to control the light-effective efficiency by using the inclined angle of the groove 100, because the inclined angle suffers inclined errors. As a result, the package 1 has poor photoluminescence effect and product reliability.

Therefore, how to solve the above problems is becoming one of the most popular issues in the art.

### SUMMARY OF THE INVENTION

In view of the above-mentioned problems of the prior art, the present invention provides a package, comprising: at least a chip having a first surface and a second surface opposing the first surface; a plurality of electrode pads formed on the first surface of the at least a chip; an encapsulant that encapsulates the at least a chip, leaving the second surface of the at least a chip and the electrode pads exposed from the encapsulant, the encapsulant having a surface leveled with the second surface of the at least a chip; a plurality of conductive bumps electrically connected to the electrode pads, respectively; a phosphor layer formed on the second surface of the chip; and a light-pervious mask formed on the encapsulant and covering the phosphor layer.

The conductive bumps are connected to the electrode pads in a variety of ways. In an embodiment, the conductive bumps are disposed on the electrode pads directly. In another embodiment, the conductive bumps are electrically connected to the electrode pads via an under-bump metallization layer. In yet another embodiment, the conductive bumps are disposed on a dielectric protection layer or a circuit re-distribution structure and electrically connected via the circuit re-distribution structure to the electrode pads.

In an embodiment, the encapsulant has a surface leveled with the electrode pads.

In an embodiment, the phosphor layer extends to a portion of the surface of the encapsulant. In another embodiment, the package has a plurality of chips, and the light-pervious mask covers the phosphor layer formed on the chips.

In another embodiment, the present invention provides a package, comprising: a substrate; at least a chip having a first surface and a second surface opposing the first surface; electrode pads formed on the first surface; a plurality of conductive bumps disposed on the electrode pads, respectively, and electrically connecting the at least a chip to the substrate; a phosphor layer formed on the second surface of the at least a chip; and a light-pervious mask formed on the substrate and the phosphor layer and covering the at least a chip

In an embodiment, the phosphor layer is further formed on a lateral surface of the at least a chip. In another embodiment, the package has a plurality of chips, and the light-pervious mask covers the phosphor layer formed on the chips.

In an embodiment, the conductive bumps are solder balls or copper bumps.

In order to obtain a package having a light-emitting element, the present invention further provides a method, comprising: disposing on a carrier board at least a chip having a first surface and a second surface opposing the first surface; forming a plurality of electrode pads on the first surface; forming on the carrier board and the at least a chip an encapsulant that covers the at least a chip, with the electrode pads exposed from the encapsulant; electrically connecting a plurality of conductive bumps respectively to the electrode pads; removing the carrier board to expose the second surface of the at least a chip; forming a phosphor layer on the second surface of the at least a chip; and forming a light-pervious mask on the encapsulant and the phosphor layer.

The present invention further provides a method of fabricating a package, the method comprising: disposing on a carrier board at least a chip having a first surface and a second surface opposing the first surface, wherein the at least a chip is disposed on the carrier board via the second surface thereof; forming a plurality of electrode pads on the first surface; disposing a plurality of conductive bumps on the electrode pads; removing the carrier board to expose the second surface of the at least a chip; disposing the at least a chip on a substrate via the conductive bumps; forming a phosphor layer on the second surface of the at least a chip; and forming on the substrate and the phosphor a light-pervious mask that covers the at least a chip.

In the present invention, the phosphor layer and the light-pervious marks are used as a reflective structure, without using the inclined angle of the groove to control the reflective efficiency as provided in the prior art. Therefore, the problem that the reflective efficiency is poor in the prior art is overcome, and the reliability of the product is improved.

In the present invention, the phosphor layer and the light-pervious mask are used as light emission adjustment structure or light converging structure, without using an inclined angle of a groove to control the reflective efficiency. Therefore, the problem of the prior art, that the reflective efficiency is poor due to the inclined errors during the wet etching process, is overcome.

### BRIEF DESCRIPTION OF DRAWINGS

The invention can be more fully understood by reading the following detailed description of the preferred embodiments, with reference made to the accompanying drawings, wherein:

FIG. 1 is a cross-sectional view of a package having a light-emitting element according to the prior art;

FIGS. 2A to 2F are cross-sectional views illustrating a method of fabricating a package having a light-emitting element of a first embodiment according to the present invention, wherein FIGS. 2C′ and 2C″ are other aspects of FIG. 2C, and FIG. 2E′ is another aspect of FIG. 2E;

FIGS. 3A to 3E are cross-sectional views illustrating a method of fabricating a package having a light-emitting element of a second embodiment according to the present invention, wherein FIGS. 3C′ is another aspect of FIG. 3C, and FIG. 3D′ is another aspect of FIG. 3D; and

FIGS. 4A to 4C are cross-sectional views illustrating a method of fabricating a package having a light-emitting element of a third embodiment according to the present invention, wherein FIGS. 4C′ is another aspect of FIG. 4C.

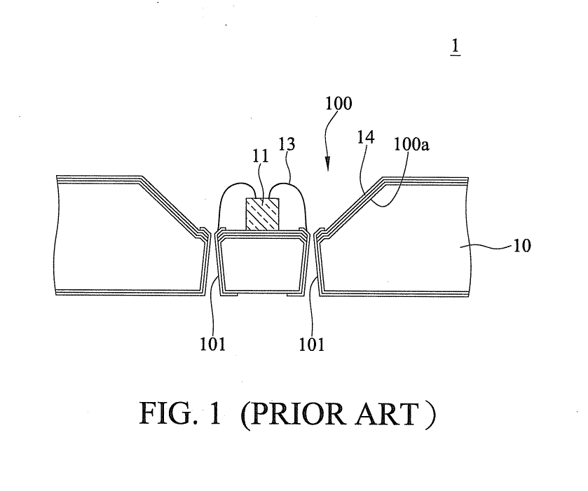

### DETAILED DESCRIPTION OF THE INVENTION

The following illustrative embodiments are provided to illustrate the disclosure of the present invention, these and other advantages and effects can be apparently understood by those in the art after reading the disclosure of this specification. The present invention can also be performed or applied by other different embodiments. The details of the specification may be on the basis of different points and applications, and numerous modifications and variations can be devised without departing from the spirit of the present invention.

### First Embodiment

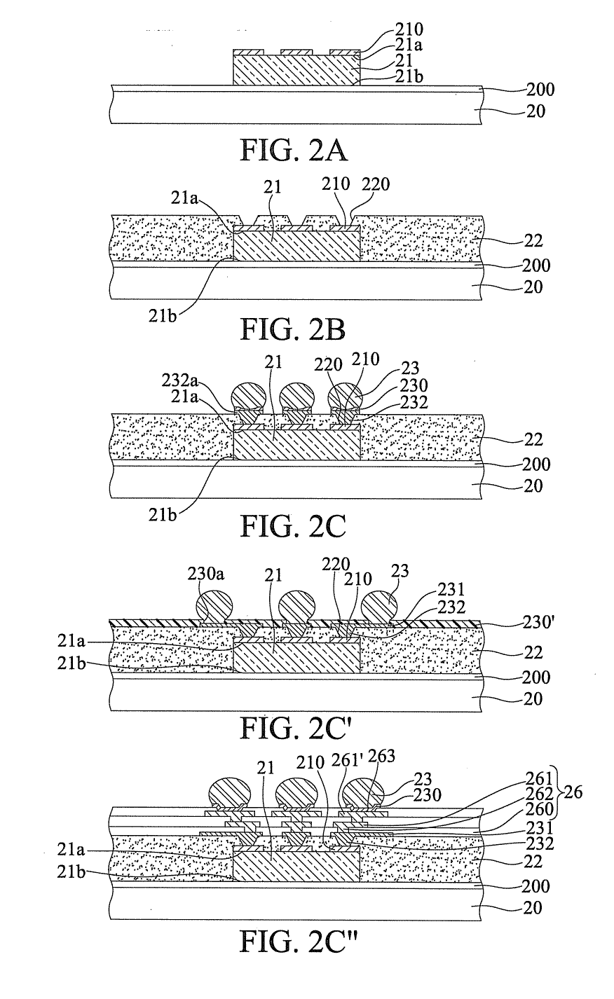

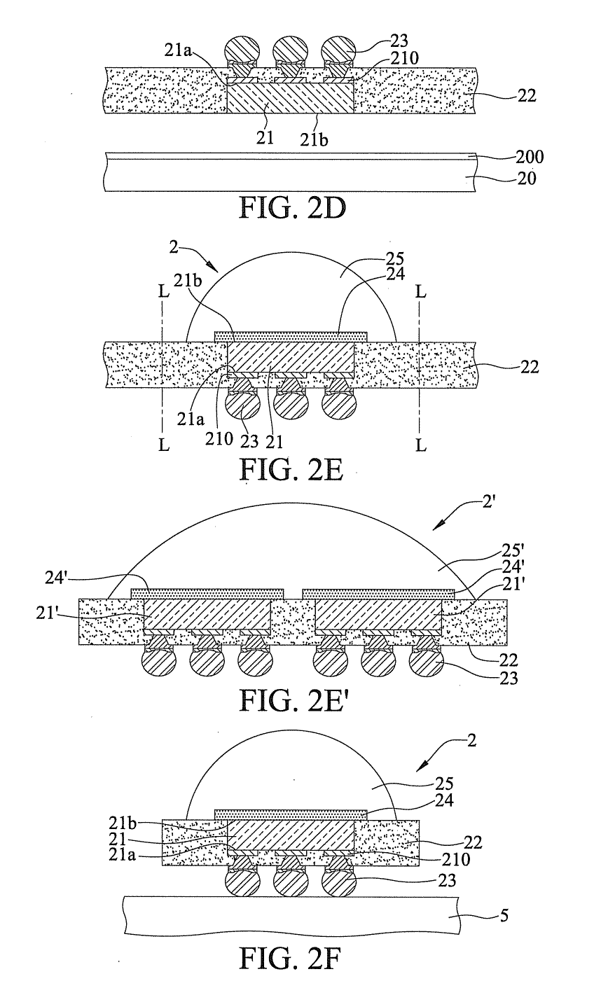

FIGS. 2A to 2F are cross-sectional views illustrating a method of fabricating a package having a light-emitting element of a first embodiment according to the present invention.

As shown in FIG. 2A, a carrier board 20 is provided and a plurality of chips 21 (only one of the chips is shown) are disposed on the carrier board 20. A delamination layer 200 is formed on the carrier board 20. The chip 21 has a first surface 21a and a second surface 21b opposing the first surface 21a. A plurality of electrode pads 210 are formed on the first surface 21a. The chip 21 is disposed on the delamination layer 200 via the second surface 21b thereof.

In an embodiment, the carrier board 20 is also adhered to the chip 21 by a heat-resistant adhesive material (not shown), other than the delamination layer 200. As no residual adhesive will remain on the chip 21, the carrier board 20 can be delaminated easily from the chip 21. In an embodiment, the chip 21 is a light-emitting element, such as a light-emitting diode (LED) or a laser diode.

As shown in FIG. 2B, an encapsulant 22 is formed on the delamination layer 200 and the chip 21 to encapsulate the chip 21. A plurality of openings 220 are formed in the encapsulant 22 for the electrode pads 210 to be exposed from the openings 220, respectively. In an embodiment, the encapsulant 22 is made by a highly light-pervious, heat-resistant and lowly deformed material such as epoxy molding compound (EMC).

As shown in FIGS. 2C, 2C′ and 2C″, conductive bumps 23 that are solder balls are implanted. The solder balls may be implanted with an under-bump metallization layer (UBM) 230, or a dielectric protection layer 230′ may be formed to limit the locations of the solder balls. In an embodiment, the dielectric protection layer 230′ is a solder mask layer or a passivation layer. In that the encapsulant 22 has the openings 220, a circuit may be formed in the openings of the encapsulant 22, for the electrode pads 210 to be connected thereto easily.

In an embodiment shown in FIG. 2C, a plurality of conductive vias 232 are respectively formed on and electrically connected to the electrode pads 210 in the openings 220. The UBM layer 230 is then formed by an electroplate process on the lands 232a of the conductive vias 232, such that the conductive bumps 23 that are solder balls allowed to be implanted on the UBM layer 230. It should be noted that a variety of composite metal bumps may be formed by the electroplate process.

In an embodiment shown in FIG. 2C′, a circuit layer 231 is formed on the encapsulant 22, conductive vias 232 are formed in the openings 220 and electrically connected to the circuit layer 231 and the electrode pads 210, and a dielectric protection layer 230′ is formed on the encapsulant 22 and the circuit layer 231. The dielectric protection layer 230′ has openings 230a. A portion of the circuit layer 231 is exposed from the openings 230a, such that the conductive bumps 23 are allowed to be disposed on the exposed portion of the circuit layer 231.

In an embodiment shown in FIG. 2C″, a circuit re-distribution structure 26 is formed on the encapsulant 22 and the circuit layer 231, and the conductive bumps 23 are then formed thereon. The circuit re-distribution layer 26 has at least one build-up dielectric layer 260, a build-up circuit layer 261 formed on the at least one build-up dielectric layer 260, and build-up conductive vias 262 formed in the build-up dielectric layer 260 and electrically connected to the build-up circuit layer 261 and the electrode pads 210. The number of the circuit re-distribution structure 26 is determined as required. In an embodiment, conductive lands 263 are formed on the outermost one of the build-up circuit layers 261′ and are electrically connected via the UBM layer 230 to the conductive bumps 23.

As shown in FIG. 2D, a process subsequent to that shown in FIG. 2C is provided. The delamination layer 200 is delaminated to remove the carrier board 20 is removed, and the second surface 21b of the chip 21 is therefore exposed.

As shown in FIG. 2E, a phosphor layer 24 is applied or sprayed on the second surface 21b of the chip 21, or extends to a portion of a surface of the encapsulant 22. A light-pervious mask 25 made of silicone is formed on the encapsulant 22 and the phosphor layer 24. A singulation process is performed along a predefined cutting line L, so as to complete the fabrication of the package 2. In an embodiment, the light-pervious mask 25 is a lens, which provides required light-reflective efficiency or changes a light pattern.

As shown in FIG. 2E′, a light-pervious mask 25′ may cover a phosphor layer 24′ formed on two chips 21′. Therefore, a single package 2′ has two chips 21′, after the singulation process is performed. Of course, the package may have more than two chips.

As shown in FIG. 2F, the package 2 is coupled to a circuit board 5 via the conductive bumps 23.

### Second Embodiment

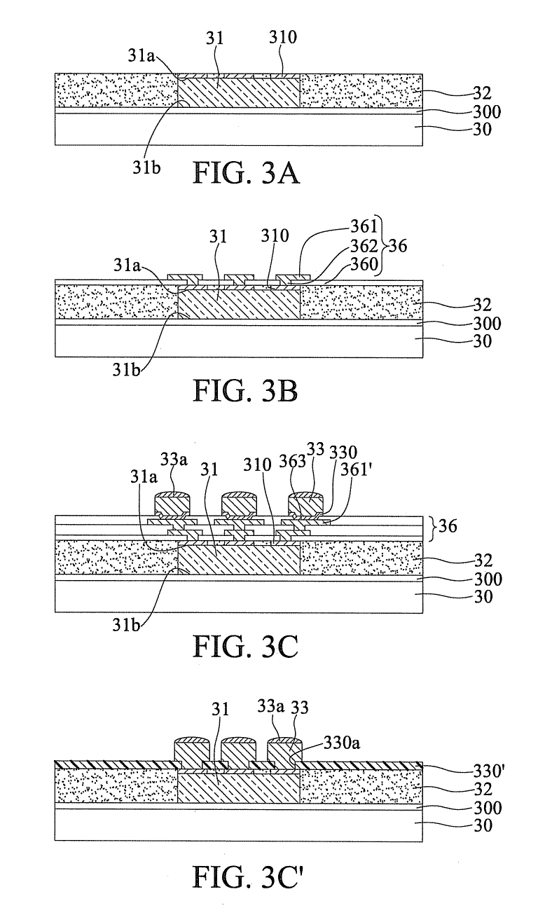

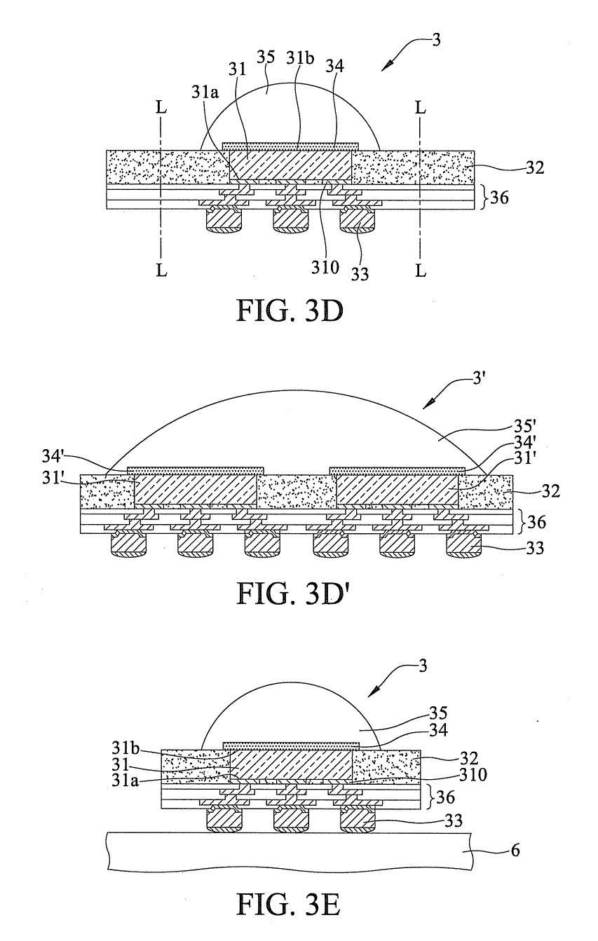

FIGS. 3A to 3E illustrate a method of a second embodiment according to the present invention. The second embodiment differs from the first embodiment in the height of the encapsulant 32 and the structure and electrical connection of the conductive bumps 33.

As shown in FIG. 3A, subsequent to the step shown in FIG. 2A, an encapsulant 32 is formed and leveled with the electrode pads 310 formed on the first surface 31a, allowing the electrode pads 310 to be exposed from the encapsulant 32.

As shown in FIG. 3B, a circuit re-distribution structure 36 (RDL) is formed on the encapsulant 32 and the electrode pads 310. The circuit re-distribution structure 36 comprises at least one build-up dielectric layer 360, a build-up circuit layer 361 formed on the build-up dielectric layer 360, and build-up conductive vias 362 formed in the build-up dielectric layer 360 and electrically connected to the build-up circuit layer 361 and the electrode pads 310

As shown in FIG. 3C, another circuit re-distribution structure 36 is further formed. That is, a plurality of the circuit re-distribution structures 36 are possible to be formed depending upon requirements. Conductive lands 363 are formed on the outermost one of the build-up circuit structures 361′. A UBM layer 330 is formed on the conductive lands 363, allowing a plurality of conductive bumps 33 to be disposed on the under-bump metallization (UBM) layer 330. In an embodiment, the conductive bumps 33 are copper bumps having a solder material 33a formed thereon.

In another embodiment, the conductive bumps 33 are implanted via the UBM layer 330 on the electrode pads 310, without the formation of the circuit re-distribution structure.

Alternatively, as shown in FIG. 3C′, a dielectric protection layer 330′ is formed on the encapsulant 32 and the electrode pads 310. The dielectric protection layer 330′ has openings 330a, for the electrode pads 310 to be exposed from the openings 330a. The conductive bumps 33 are implanted on the electrode pads in the openings 330a.

As shown in FIG. 3D, the delamination layer 300 is delaminated, to remove the carrier board 30. A phosphor layer 34 is formed on the second surface 31b of the chip 31 and a portion of a surface of the encapsulant 32. A light-pervious mask 35 is formed on the encapsulant 32 and the phosphor layer 34. A singulation process is performed along a predefined cutting line L, so as to form another package 3.

As shown in 3D′, a light-pervious mask 35′ covers a phosphor layer 34′ formed on a plurality of chips 31′. In this embodiment, the package 3′ has two chips 31′.

As shown in FIG. 3E, the package 3 is mounted on a circuit board 6 via the conductive bumps 33.

In the present invention, the chip 21, 31 is embedded in the encapsulant 22, 32 by an embedded wafer level packaging technique, without using an etching liquid to form a groove and a reflective surface. Therefore, the process is simplified, and the cost is greatly reduced.

The unit per hour (UPH) of the present invention is far greater than that of the prior art, because the method of the present invention is simpler than the prior art.

### Third Embodiment

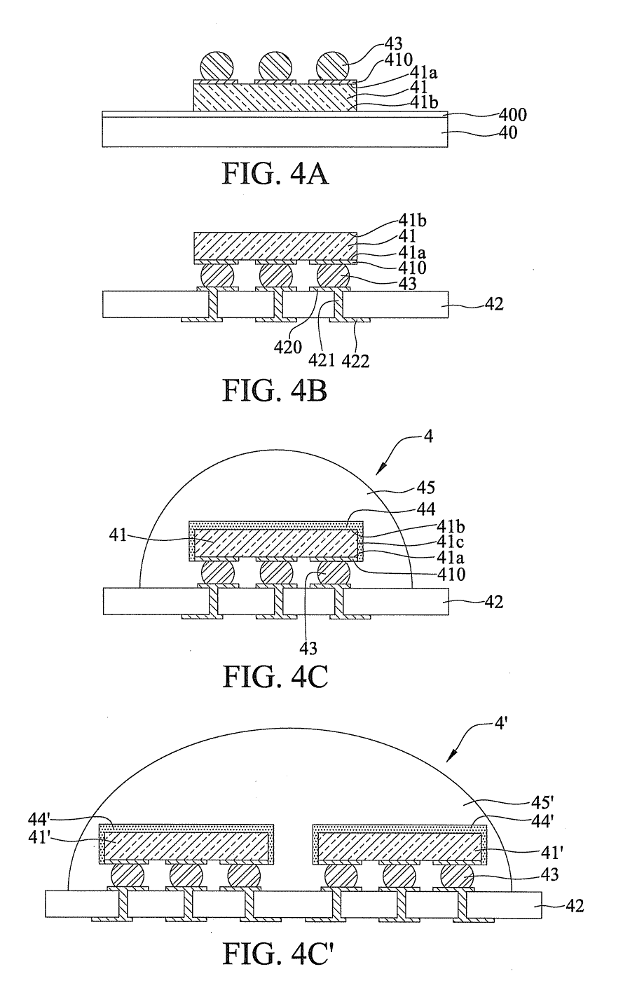

FIGS. 4A to 4C illustrate a method of a third embodiment according to the present invention. The third embodiment differs from the first and second embodiments in that the chip 41 is not encapsulated by an encapsulant. And, the structure and electrical connection of the conductive bumps 43 are also different.

As shown in FIG. 4A, subsequent to the process shown in FIG. 2A, a plurality of conductive bumps 43 are disposed on electrode pads on a first surface 41a of a chip 41, respectively. In the third embodiment, the conductive bumps 43 are solder balls, and are formed by a screen printing method.

As shown in FIG. 4B, the delamination layer 400 is delaminated, to remove the carrier board 40, so as to expose the second surface 41b of the chip 41. Through the use of the conductive bumps 43, the chip 41 is disposed on a substrate 42 that has circuits 420 and 422 and conductive through holes 421. The conductive bumps 43 are electrically connected to the circuits 420.

As shown in FIG. 4C, a phosphor layer 44 is sprayed on a second surface 41b and a lateral surface 41c of the chip 41, and a light-pervious mask 45 is formed on the substrate 42 and the phosphor layer 44, so as to form another package 4.

As shown in FIG. 4C′, a plurality of chips 41′ are disposed on the substrate 42, and the light-pervious mask 45′ covers a phosphor layer 44′ formed on the chips 41′. In this embodiment, the single package 4′ has two chips 41′.

In subsequent processes, solder balls (not shown) are disposed on the circuit 422 on the substrate 42 of the package 4, for a circuit board to be combined therewith.

In the third embodiment, because the encapsulant is not formed, a singulation process is omitted. Any number of chips may be disposed on the substrate 42 based on needs in design.

According to the method of fabricating a package having a light-emitting element, a phosphor layer and a light-pervious mask are formed on the chip, and the chip is free from being disposed in the groove of a silicon substrate. Therefore, the wet etching process is omitted, and the fabrication cost is greatly reduced.

In the present invention, the phosphor layer and the light-pervious marks are used as a reflective structure, without using the inclined angle of the groove to control the reflective efficiency. Therefore, the problem that the reflective efficiency is poor is overcome, and the reliability of the product is improved.

The foregoing descriptions of the detailed embodiments are only illustrated to disclose the features and functions of the present invention and not restrictive of the scope of the present invention. It should be understood to those in the art that all modifications and variations according to the spirit and principle in the disclosure of the present invention should fall within the scope of the appended claims.

1. A package, comprising:
at least a chip having a first surface and a second surface opposing the first surface, a plurality of electrode pads being formed on the first surface of the at least a chip;
an encapsulant for encapsulating the at least a chip, leaving the second surface of the chip and the electrode pads exposed from the encapsulant, the encapsulant having a surface leveled with the second surface of the at least a chip;
a plurality of conductive bumps electrically respectively connected to the electrode pads;
a phosphor layer formed on the second surface of the at least a chip; and
a light-pervious mask formed on the encapsulant and covering the phosphor layer.

2. The package of claim 1, further comprising an under-bump metallization layer that electrically connects the conductive bumps to the electrode pads.

3. The package of claim 1, further comprising a dielectric protection layer formed on the encapsulant and having openings corresponding in position to the electrode pads, for the conductive bumps to be disposed in the openings and electrically connected to the electrode pads.

4. The package of claim 2, further comprising conductive vias formed in the encapsulant and electrically connected to the electrode pads, the conductive vias having ends electrically connected to the conductive bumps via the under-bump metallization layer.

5. The package of claim 1, further comprising:
a circuit layer formed on the encapsulant;
conductive vias formed in the encapsulant and electrically connected to the circuit layer and the electrode pads; and
a dielectric protection layer formed on the encapsulant and the circuit layer and having openings,
wherein a portion of the circuit layer is exposed from the openings, and the conductive bumps are disposed on the exposed portion of the circuit layer.

6. The package of claim 1, further comprising:
a circuit layer formed on the encapsulant;
conductive vias formed in the encapsulant and electrically connected to the circuit layer and the electrode pads; and
a circuit re-distribution structure formed on the encapsulant and the circuit layer, the circuit re-distribution structure including:
a build-up dielectric layer;
a build-up circuit layer formed on the build-up dielectric layer;
build-up conductive vias formed in the build-up dielectric layer and electrically connected to the build-up circuit layer and the circuit layer; and
a plurality of conductive lands formed on the build-up circuit layer and electrically connected on the under-bump metallization layer.

7. The package of claim 1, wherein the surface of the encapsulant is leveled with the electrode pads.

8. The package of claim 7, further comprising a circuit re-distribution structure formed on the encapsulant and the electrode pads and including:
a build-up dielectric layer;
a build-up circuit layer formed on the build-up dielectric layer;
build-up conductive vias formed in the build-up dielectric layer and electrically connected to the build-up circuit layer and the electrode pad; and
a plurality of conductive lands formed on the build-up circuit layer and electrically connected on the under-bump metallization layer.

9. The package of claim 7, further comprising a circuit re-distribution structure formed on the encapsulant and the electrode pads and including:
a build-up dielectric layer;
a build-up circuit layer formed on the build-up dielectric layer;
build-up conductive vias formed in the build-up dielectric layer and electrically connected to the build-up circuit layer and the electrode pads; and
a dielectric protection layer formed on the build-up dielectric layer and having openings,
wherein a portion of the build-up circuit layer is exposed from the openings, and the conductive bumps are disposed on the exposed portion of the build-up circuit layer.

10. The package of claim 1, wherein the conductive bumps are solder balls, or copper bumps having a solder material formed thereon.

11. The package of claim 1, wherein the phosphor layer is further formed on a portion of the surface of the encapsulant.

12. The package of claim 1, wherein the light-pervious mask covers the phosphor layer formed on the at least a chip.

13. The package of claim 1, further comprising a circuit board, on which the at least a chip is disposed by the conductive bumps.

14. A package, comprising:
a substrate;
at least a chip each having a first surface and a second surface opposing the first surface, electrode pads being formed on the first surface;
a plurality of conductive bumps respectively disposed on the electrode pads and electrically connecting the at least a chip to the substrate;
a phosphor layer formed on the second surface of the at least a chip; and
a light-pervious mask formed on the substrate and the phosphor layer and covering the at least a chip.

15. The package of claim 14, wherein the conductive bumps are solder, balls, solder balls having an under-bump metallization layer, or copper bumps having an under-bump metallization layer.

16. The package of claim 14, wherein the phosphor layer is further formed on a lateral surface of the at least a chip.

17. The package of claim 14, wherein the light-pervious mask covers the phosphor layer formed on the at least a chip.

18. A method, comprising:
disposing on a carrier board at least a chip having a first surface and a second surface opposing the first surface, the first surface having a plurality of electrode pads formed thereon;
forming on the carrier board and the at least a chip an encapsulant that covers the at least a chip, leaving the electrode pads exposed from the encapsulant;
electrically connecting a plurality of conductive bumps to the electrode pads, respectively;
removing the carrier board to expose the second surface of the at least a chip;
forming a phosphor layer on the second surface of the at least a chip; and
forming a light-pervious mask on the encapsulant and the phosphor layer.

19. The method of claim 18, further comprising forming a delamination layer between the carrier board and the second surface of the chip, so as to facilitate the removal of the carrier board.

20. The method of claim 18, further comprising electrically connecting the conductive bumps to the electrode pads via an under-bump metallization layer.

21. The method of claim 18, further comprising, prior to the electrical connection of the plurality of conductive bumps respectively to the electrode pads, forming on the encapsulant a dielectric protection layer having openings corresponding in position to the electrode pads, wherein the conductive bumps are disposed on the electrode pads in the openings.

22. The method of claim 18, wherein the encapsulant has a plurality of openings, for the electrode pads to be respectively exposed from the openings.

23. The method of claim 22, further comprising forming in the openings conductive vias electrically connected to the electrode pads and having ends electrically connected to the conductive bumps via an under-bump metallization layer.

24. The method of claim 22, further comprising:
forming a circuit layer on the encapsulant;
forming in the openings conductive vias electrically connected to the circuit layer and the electrode pads; and
forming on the encapsulant and the circuit layer a dielectric protection layer having openings,
wherein a portion of the circuit layer is exposed from the openings, and the conductive bumps are disposed on the exposed portion of the circuit layer.

25. The method of claim 22, further comprising:
forming a circuit layer on the encapsulant;
forming in the openings conductive vias electrically connected to the circuit layer and the electrode pads; and
forming on the encapsulant and the circuit layer a circuit re-distribution structure, the circuit re-distribution structure including:
a build-up dielectric layer;
a build-up circuit layer formed on the build-up dielectric layer;
build-up conductive vias formed in the build-up dielectric layer and electrically connected to the build-up circuit layer and the circuit layer; and
conductive lands formed on the build-up circuit layer and electrically connected via an under-bump metallization layer to the conductive bumps.

26. The method of claim 18, wherein the encapsulant has a surface leveled with the electrode pads.

27. The method of claim 26, further comprising, prior to the electrical connection of the plurality of conductive bumps respectively to the electrode pads, forming on the encapsulant and the electrode pads a circuit re-distribution structure, the circuit re-distribution structure including:
a build-up dielectric layer;
a build-up circuit layer formed on the build-up dielectric layer;
build-up conductive vias formed in the build-up dielectric layer and electrically connected to the build-up circuit layer and the electrode pads; and
a plurality of conductive lands formed on the build-up circuit layer and electrically connected via an under-bump metallization layer to the conductive bumps.

28. The method of claim 26, further comprising, prior to electrically connecting the plurality of conductive bumps to the electrode pads, respectively, forming on the encapsulant and the electrode pads a circuit re-distribution structure, the circuit re-distribution structure including:
a build-up dielectric layer;
a build-up circuit layer formed on the build-up dielectric layer;
build-up conductive vias formed in the build-up dielectric layer and electrically connected to the build-up circuit layer and the electrode pads; and
a dielectric protection layer formed on the build-up dielectric layer and having openings,
wherein a portion of the circuit layer is exposed from the openings, for the conductive bumps to be disposed on the exposed portion of the circuit layer.

29-33. (canceled)

34. A method, comprising:
disposing on a carrier board at least a chip having a first surface and a second surface opposing the first surface, wherein the first surface has a plurality of electrode pads formed thereon and the at least a chip is disposed on the carrier board via the second surface thereof;
disposing a plurality of conductive bumps on the electrode pads;
removing the carrier board to expose the second surface of the at least a chip;
disposing the at least a chip on a substrate by the conductive bumps;
forming a phosphor layer on the second surface of the at least a chip; and
forming on the substrate and the phosphor layer a light-pervious mask that covers the at least a chip.

35. The method of claim 34, further comprising forming a delamination layer between the carrier board and the second surface of the at least a chip, so as to facilitate the removal of the carrier board.

36-38. (canceled)

39. The method of claim 18, wherein the conductive bumps are solder balls, or copper bumps having a solder material disposed thereon.

40. The method of claim 18, wherein the phosphor layer is further formed on a portion of a surface of the encapsulant.

41. The method of claim 18, wherein the light-pervious mask covers the phosphor layer formed on the at least a chip.

42. The method of claim 18, further comprising performing a singulation process, after the formation of the light-pervious mask.

43. The method of claim 18, further comprising combining the conductive bumps with the circuit board, after the formation of the light-pervious mask.

44. The method of claim 34, wherein the conductive bumps are solder balls, solder balls having an under-bump metallization layer, or copper bumps having an under-bump metallization layer.

45. The method of claim 34, wherein the phosphor layer is further formed on a lateral surface of the at least a chip.

46. The method of claim 34, wherein the light-pervious mask covers the phosphor layer formed on the at least a chip.
